(19) United States
(12) Patent Application Publication
(10) Pub. No.: US 2008/0061443 A1
(43) Pub. Date: Mar. 13, 2008

(54) METHOD OF MANUFACTURING SEMICONDUCTOR DEVICE

(76) Inventor: Jin-Ha Park, Gyeonggi-do (KR)

Correspondence Address: SHERR & NOURSE, PLLC, 620 HERNDON PARKWAY, SUITE 200, HERNDON, VA, 20170, US

(21) Appl. No.: 11/847,649

(22) Filed: Aug. 30, 2007

(30) Foreign Application Priority Data
Sep. 13, 2006 (KR) 10-2006-0088428

(51) Int. Cl. H01L 23/52; H01L 21/46

(52) U.S. Cl. 257/774; 438/455; 257/E23.127; 257/E23.141

(57) ABSTRACT

A method for manufacturing a semiconductor device including at least one of the following steps. Forming a first semiconductor substrate including a first conductive pattern. Adhering a second semiconductor including a second conductive pattern on the first semiconductor substrate using adhesive paste. Forming a through hole by patterning the first semiconductor substrate and the second semiconductor substrate. Forming a through electrode by depositing a barrier metal on the through hole and burying and planarizing metal materials.

The present application claims priority under 35 U.S.C. 119 to Korean Patent Application No. 10-2006-0088428 (filed on Sep. 13, 2006), which is hereby incorporated by reference in its entirety.

### BACKGROUND

Aspects of semiconductor technology have focused on devices that are slim and lightweight. System-on-chip (SoC) technology has been developed in order to reduce the individual size of a mounted component. With SoC, a plurality of individual devices can be provided on a single chip.

System-in-package (SIP) technology may also be required to integrate a plurality of individual devices into a single package. SIP packaging is an expansion of the multi-chip module (MCM) concept. SIP packaging can be constructed to arrange a plurality of silicon chips horizontally and vertically in a single package. On the other hand, MCM packaging may be constructed to arrange horizontal mounting of components in a side-by-side fashion. The use of SIP may be chiefly applicable for vertically mounting a plurality of chips in a stacked configuration.

Passive devices such as resistors, capacitors and inductors may be mounted on a system board to enhance electrical characteristics of an active device and also for power input noise reduction.

The value of the inductance of a capacitor can be determined depending on the proximity to the device formed on each chip. As the capacitor becomes closer in proximity to the device formed on each chip, it may implement a low inductance. There can be difficulties, however, in implementing several kinds of devices having various design rules in one chip.

### SUMMARY

Embodiments relate to a method for manufacturing a semiconductor device including at least one of the following steps: forming a first semiconductor substrate including a first conductive pattern. Adhering a second semiconductor substrate including a second conductive pattern on and/or over the first semiconductor substrate using adhesive paste. Forming a through hole by patterning the first semiconductor substrate and the second semiconductor substrate. Forming a through electrode by depositing a barrier metal on and/or over the through hole and burying and planarizing metal materials.

### DRAWINGS

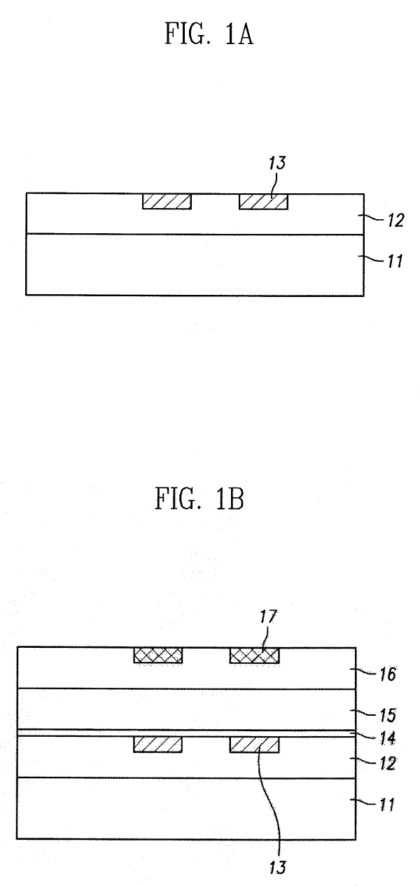

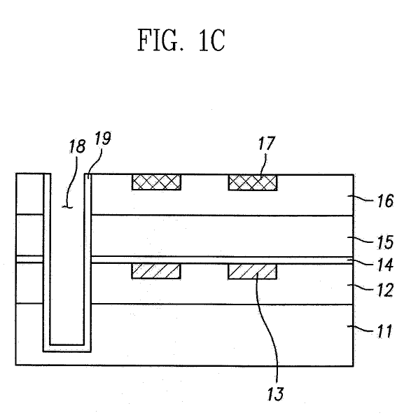

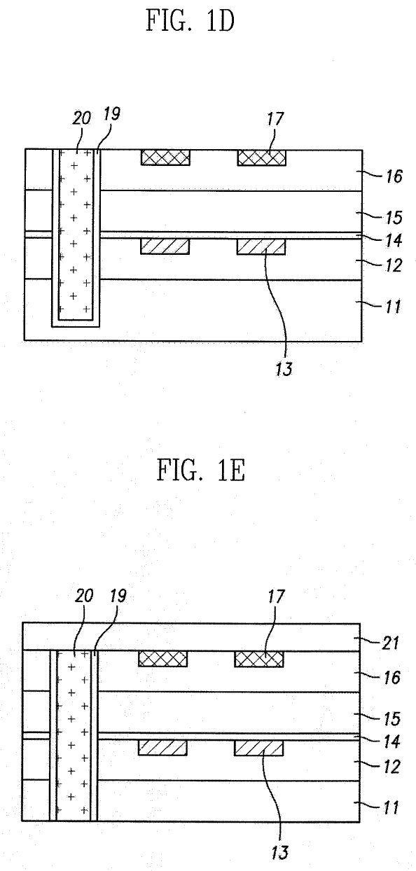

Example FIGS. 1A to 1E illustrate a method for manufacturing a semiconductor device, in accordance with embodiments.

### DESCRIPTION

As illustrated in example FIG. 1A, first insulating layer 12 is formed on and/or over first semiconductor substrate 11. First conductive patterns 13 having a predetermined conductivity are provided on and/or over first insulating layer 12. First conductive patterns 13 may be a source/drain region, a gate electrode or a bit line, a lower wiring or an upper electrode of a capacitor. First conductive patterns 13 may be formed using a photolithographic/etching process or a damascene process.

As illustrated in example FIG. 1B, once first conductive patterns 13 are formed on and/or over first insulating layer 12, second semiconductor substrate 15 can be adhered to first insulating layer 12 using adhesive paste 14. Adhesive paste 14 may be an epoxy-based adhesive or a polymeric-based bonding material. Second insulating layer 16 can be formed on and/or over second semiconductor substrate 15 and second conductive patterns 17 having a predetermined conductivity can be formed on and/or over second insulating layer 16. Second conductive patterns 17 may be a source/drain region, a gate electrode or a bit line, a lower wiring or an upper electrode of a capacitor. Second conductive patterns 17 may be formed using a photolithographic/etching process or a damascene process.

As illustrated in example FIG. 1C, through hole 18 can be formed by patterning first semiconductor substrate 11 and second semiconductor substrate 15. Barrier layer 19 composed of a metal, such as Ti, TiN, Ti/TiN, Ta, TaN, Ta/TaN, TaN/Ta, Co, a Co-compound, Ni, a Ni-compound, W, a W-compound, nitride and the like can be deposited at the inner wall of through hole 18 using a metal thin film deposition method such as physical vapor deposition (PVD), sputtering, evaporation, laser ablation (LA), atomic layer deposition (ALD), and chemical vapor deposition (CVD) and the like.

As illustrated in example FIG. 1D, a material composed of a metal such as Al, an Al-compound, Cu, a Cu-compound, W, a W-compound, and the like, etc. can be buried in through hole 18 using a process such as physical vapor deposition (PVD), sputtering, evaporation, laser ablation (LA), electro copper plating (ECP), atomic layer deposition (ALD), chemical vapor deposition (CVD), and the like. Through electrode 20 may then be formed by planarizing the upper surface of the metallic materials using a process such as chemical mechanical polishing (CMP) and an etch back, and the like.

As illustrated in example FIG. 1E, protective layer 21 is deposited on and/or over second insulating layer 16. Protective layer 21 can be composed of a material such as such as SiO₂, BPSG, TEOS, SiN and the like. Protective layer 21 may be deposited using an electric furnace, CVD, PVD, and the like. Through electrode 20 can then be exposed at the lowermost portion of first semiconductor substrate 11 using a back grinding process.

In accordance with embodiments, a semiconductor device manufacturing process may include adhering first semiconductor substrate 11 to second semiconductor substrate 15 using adhesive paste 14, and forming through electrode 20 on and/or over first semiconductor substrate 11 and second semiconductor substrate 15.

In accordance with embodiments, respective through electrodes 20 can be formed on and/or over first semiconductor substrate 11 and second semiconductor substrate 15. Accordingly the through electrodes formed on and/or over first semiconductor substrate 11 and those formed on and/or over second semiconductor substrate 15 may be adhered to each other using adhesive materials such as a copper plug, making it also possible to manufacture a semiconductor device using a method electrically connecting first semiconductor substrate 11 to second semiconductor substrate 15.

Embodiments provide a method for manufacturing a semiconductor device using SIP that can reduce the number of implant layers, and thus, reduce the process times to obtain a highly-integrated integrated circuit.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
providing a first semiconductor substrate including a first conductive pattern;
adhering a second semiconductor substrate including a second conductive pattern on the first semiconductor substrate using an adhesive paste;
forming a through hole by patterning the first semiconductor substrate and the second semiconductor substrate; and
forming a through electrode by depositing a barrier metal in the through hole and burying and planarizing at least one metallic material.

2. The method of claim 1, further comprising depositing a protective layer over the second semiconductor substrate and exposing the through electrode to a lowermost surface of the first semiconductor substrate after forming the through electrode.

3. The method of claim 2, wherein the through electrode is exposed using a back-grinding process.

4. The method of claim 1, wherein the adhesive paste comprises an epoxy-based adhesive or plastic-based bonding material.

5. The method of claim 1, wherein the adhesive paste comprises a polymeric-based bonding material.

6. The method of claim 1, wherein the barrier metal is deposited at an inner wall of the through hole using a metal thin film deposition method.

7. The method of claim 6, wherein the metal thin film deposition method comprises at least one of physical vapor deposition, sputtering, evaporation, laser ablation, atomic layer deposition, and chemical vapor deposition.

8. The method of claim 7, wherein the barrier metal comprises at least one of Ti, TiN, Ti/TiN, Ta, TaN, Ta/TaN, TaN/Ta, Co, a Co-compound, Ni, a Ni-compound, W, a W-compound and a nitride.

9. The method of claim 1, wherein the at least one metallic material is buried using a metal thin film deposition method.

10. The method of claim 9, wherein the metal film deposition method comprises at least one of physical vapor deposition, sputtering, evaporation, laser ablation, electro copper plating, atomic layer deposition, and chemical vapor deposition.

11. The method of claim 10, wherein the metallic material is planarized using chemical mechanical polishing and an etch back process.

12. The method of claim 11, wherein the at least one metallic material comprises at least one of Al, an Al-compound, Cu, a Cu-compound, W, and a W-compound.

13. An apparatus comprising:
a first semiconductor substrate;
a first insulating layer provided over the first semiconductor substrate;
at least one first conductive pattern having a predetermined conductivity provided over the first insulating layer;
a second semiconductor substrate;
a second insulating layer provided over the second semiconductor substrate;
at least one second conductive pattern having a predetermined conductivity provided over the second semiconductor substrate;
an adhesive paste for adhering second semiconductor substrate to the second semiconductor substrate;
a through hole formed in the first semiconductor substrate and the second semiconductor substrate; and
a through electrode.

14. The apparatus of claim 13, wherein the adhesive paste comprises at least one of an epoxy-based material and a polymeric-based material.

15. The apparatus of claim 14, wherein the second semiconductor substrate is adhered to the second semiconductor substrate at the first insulating layer.

16. The apparatus of claim 13, further comprising a protective layer formed over the second insulating layer, the at least one second conductive patterns and the through electrode.

17. The apparatus of claim 16, wherein the protective layer comprises at least one of SiO₂, BPSG, TEOS and SiN.

18. The apparatus of claim 13, wherein a surface of the through electrode is exposed at a lower most surface of the first semiconductor substrate.

19. The apparatus of claim 13, further comprising a barrier metal deposited at an inner wall of the through hole.

20. The apparatus of claim 19, wherein the barrier metal comprises at least one of Ti, TiN, Ti/TiN, Ta, TaN, Ta/TaN, TaN/Ta, Co, a Co-compound, Ni, a Ni-compound, W, a W-compound and a nitride.
